(19) United States
(12) Patent Application Publication
(10) Pub. No.: US 2013/0147534 A1
(43) Pub. Date: Jun. 13, 2013

(54) MASTER SLAVE FLIP-FLOP WITH LOW POWER CONSUMPTION

(71) Applicants: Zhihong Cheng, Suzhou (CN); Shixiang Nie, Suzhou (CN); Yang Wang, Suzhou (CN)

(72) Inventors: Zhihong Cheng, Suzhou (CN); Shixiang Nie, Suzhou (CN); Yang Wang, Suzhou (CN)

(73) Assignee: FREESCALE SEMICONDUCTOR, INC., Austin, TX (US)

(21) Appl. No.: 13/605,984

(22) Filed: Sep. 6, 2012

(30) Foreign Application Priority Data
Dec. 13, 2011 (CN) 201110463126.9

(51) Int. Cl. H03K 3/289

(52) U.S. Cl. 327/202

(57) ABSTRACT

In a master-slave D flip-flop, the master latch has first and second three-state stages and a feedback stage for positive feedback from the data outputs of the first and second three-state stages to the data input of the second three-state stage. The slave latch has third and fourth three-state stages and a feedback stage for positive feedback from the data outputs of the third and fourth three-state stages to the data input of the fourth three-state stage. Clock signals are applied from a clock signal source to the clock inputs of a clock switch element in one of the three-state stages whose clock signal is shared with another of the three-state stages, reducing the number of clock switches and clock switch power consumption. Data inverters also may be shared between a three-state stage of the master latch and a three-state stage of the slave latch.

### BACKGROUND OF THE INVENTION

The present invention is directed to a digital logic circuit and, more particularly, to a master-slave flip-flop with low power consumption.

Master-slave flip-flops are widely used in digital logic circuits. Typically a master-slave D flip-flop has two gated latches connected in series and driven by a two-phase clock signal. The master latch registers the value of the input signal at the trailing edge of a first phase of the clock signal, which is the active clock edge for the master latch. The slave latch registers the value of the output signal from the master latch at the trailing edge of the following, opposite phase of the clock signal, which is the active clock edge for the slave latch. A common configuration of flip-flop is a D flip-flop.

Each of the master and slave latches may have two three-state stages connected in series and a feedback stage. The three-state stages have a high impedance (OFF) output state, as a function of assertion of clock signals, and asserted and de-asserted output states, as a function of input signals. Typically, the three-state stages and the feedback stages are inverter stages. Each three-state stage may include complementary clock switch elements controlled by complementary clock signals, connected in series with complementary data inverters that receive data input signals at their inputs.

A large number of flip-flops may be used in a typical integrated circuit (IC) so the power consumption of the flip-flops is often significant. Various techniques have been used to reduce the power consumption of flip-flops. Clock signal switching inherently is usually much more frequent than data signal switching and typically accounts for a larger proportion of the power consumption than data signal switching. One known technique for reducing power consumption involves gating (switching OFF) the clock signals when the flip-flop output is equal to its input. Another known technique uses dynamic logic, instead of static logic, with a view to reducing the number of components. However, most known techniques used to reduce power consumption have the disadvantages of increasing circuit area and/or leading to performance penalties such as increased set-up or hold times, clock glitches and risk of unstable operation.

Thus, it would be advantageous to be able to reduce power consumption of flip-flops in an IC while avoiding some or all of these disadvantages.

### BRIEF DESCRIPTION OF THE DRAWINGS

The present invention is illustrated by way of example and is not limited by embodiments thereof shown in the accompanying figures, in which like references indicate similar elements. Elements in the figures are illustrated for simplicity and clarity and have not necessarily been drawn to scale.

FIG. 1 is a schematic circuit diagram of a known master-slave D flip-flop;

FIG. 2 is a timing diagram of signals appearing in operation of the D flip-flop of FIG. 1, when the D flip-flop is operating as a clock divider;

FIG. 3 is a schematic circuit diagram of a master-slave D flip-flop in accordance with one embodiment of the invention, given by way of example;

FIG. 4 is a timing diagram of signals appearing in operation of the D flip-flop of FIG. 3, when the D flip-flop is working as a clock divider;

FIG. 5 is a schematic circuit diagram of a master-slave D flip-flop in accordance with another embodiment of the invention, given by way of example;

FIG. 6 is a timing diagram of signals appearing in operation of the D flip-flop of FIG. 5, when the D flip-flop is working as a clock divider;

FIG. 7 is a schematic circuit diagram of a master-slave D flip-flop in accordance with yet another embodiment of the invention, given by way of example; and

FIG. 8 is a timing diagram of signals appearing in operation of the D flip-flop of FIG. 7, when the D flip-flop is working as a clock divider.

### DETAILED DESCRIPTION OF PREFERRED EMBODIMENTS OF THE INVENTION

The following examples of flip-flops are described with positive voltage signals corresponding to asserted, logically true values and zero voltage signals corresponding to de-asserted, logically false values. However, it will be appreciated that the D flip-flops described may be adapted to zero (or negative) voltage signals corresponding to asserted, logically true values and positive voltage signals corresponding to de-asserted, logically false values. Further, specific conductivity types or polarity of potentials have been described in the examples but it will appreciated that the examples may be adapted to opposite conductivity types and polarities

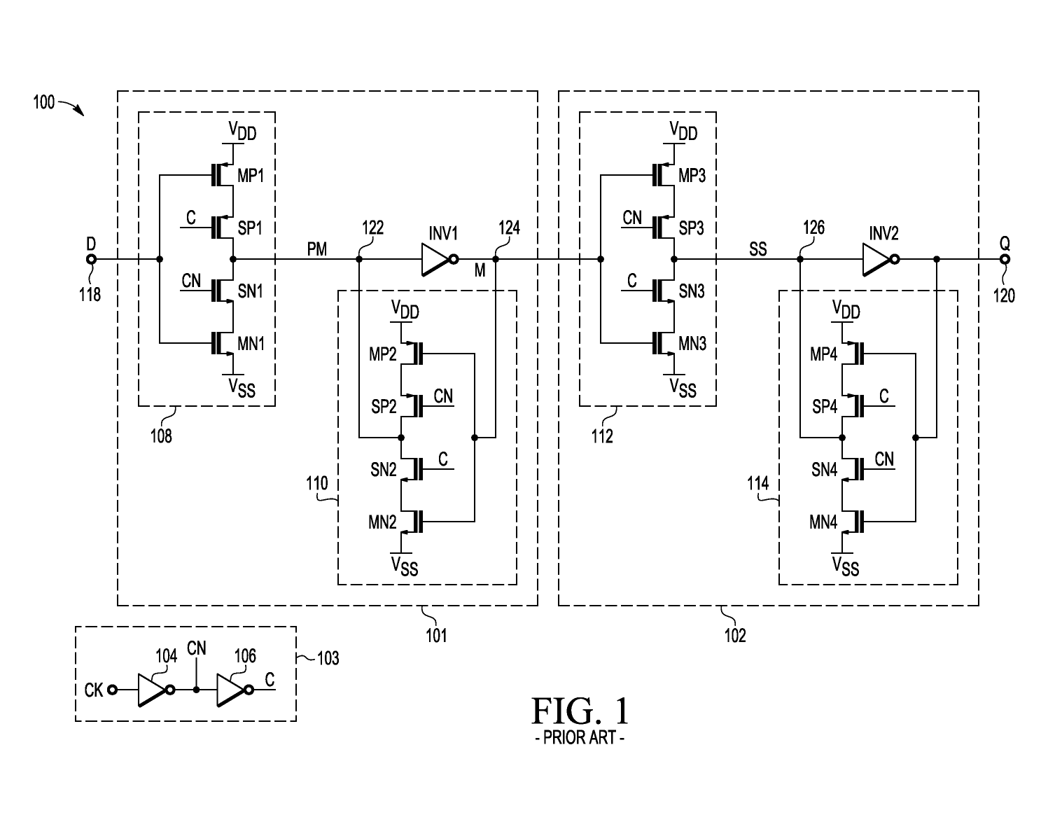

FIG. 1 illustrates a known master-slave D flip-flop 100 including a master latch 101 and a slave latch 102. A clock source 103 receives a system clock signal CK and includes a pair of inverters 104 and 106 connected in series to generate from the system clock signal CK and supply to the flip-flop 100 an anti-phase clock signal CN and an in-phase clock signal C.

The master latch 101 has first and second three-state stages 108 and 110 having respective data inputs, clock inputs and data outputs and a first feedback stage INV1 for positive feedback from the data outputs of the first and second three-state stages 108 and 110 to the data input of the second three-state stage 110. The slave latch 102 includes third and fourth three-state stages 112 and 114 having respective data inputs, clock inputs and data outputs, and a second feedback stage INV2 for positive feedback from the data outputs of the third and fourth three-state stages 112 and 114 to the data input of the fourth three-state stage 114. The three-state stages 108, 110, 112 and 114 are inverter stages and the first and second feedback stages are also inverters.

The data input of the first three-state inverter stage 108 receives data input signals from an input terminal 118. The data input of the third three-state inverter stage 112 receives data signals from the output of the first feedback inverter INV1 and of the master latch 101. The output signal Q of the slave latch 102 and of the flip-flop 100 appears at an output terminal 120 of the second feedback inverter INV2. The clock inputs of both the master latch 101 and the slave latch 102 receive the clock signals C and CN from the clock signal source 103. The data signal outputs of the first and fourth three-state inverter stages 108 and 114 are functions of their respective data inputs when the clock signals C and CN are respectively de-asserted and asserted. The first and fourth three-state inverter stages 108 and 114 are OFF (high impedance data signal outputs) when the clock signals C and CN are respectively asserted and de-asserted. The data signal outputs of the second and third three-state inverter stages 110 and 112 are functions of their respective data inputs when the clock signals C and CN are respectively asserted and de-asserted. The second and third three-state inverter stages 110 and 112 are OFF (high impedance data signal outputs) when the clock signals C are respectively de-asserted and asserted.

The three-state inverter stages 108 to 114 include pairs of data inverter elements having p-type and n-type complementary metal-oxide-semiconductor (CMOS) devices MP1-MN1, MP2-MN2, MP3-MN3, and MP4-MN4, having signal paths connected to high and low voltage power supplies V_{DD} and V_{SS} and control electrodes (gates) connected to receive the respective data input signals of the three-state inverter stages 108 to 114. The three-state inverter stages 108 to 114 also include pairs of clock switch elements SP1-SN1, SP2-SN2, SP3-SN3, and SP4-SN4, having p-type and n-type CMOS devices having signal paths connected in series with each other and in series with the signal paths of the data inverter element devices MP1-MN1, MP2-MN2, MP3-MN3, and MP4-MN4. The clock switch elements SP1, SN2, SN3 and SP4 receive the clock signals C on their control electrodes, whereas the clock switch elements SN1, SP2, SP3 and SN4 receive the opposite phase clock signals CN on their control electrodes.

The output signals PM of the first and second three-state inverter stages 108 and 110 appear at a node 122 connected to the signal paths of the clock switch elements SP1-SN1 and SP2-SN2 and to the input of the first feedback inverter INV1. The data inputs of the third three-state inverter stage 112 are provided by the output signal M of the first feedback inverter INV1 at a node 124. The output signals SS of the third and fourth three-state inverter stages 112 and 114 appear at a node 126 connected to the signal paths of the clock switch elements SP3-SN3 and SP4-SN4 and to the input of the second inverter INV2. The output Q at the output of the slave latch 102 and of the D flip-flop 100 at the output terminal 120 is applied to the control electrodes of the data inverter element devices MP4-MN4 to provide the positive feedback of the fourth three-state inverter stage 114.

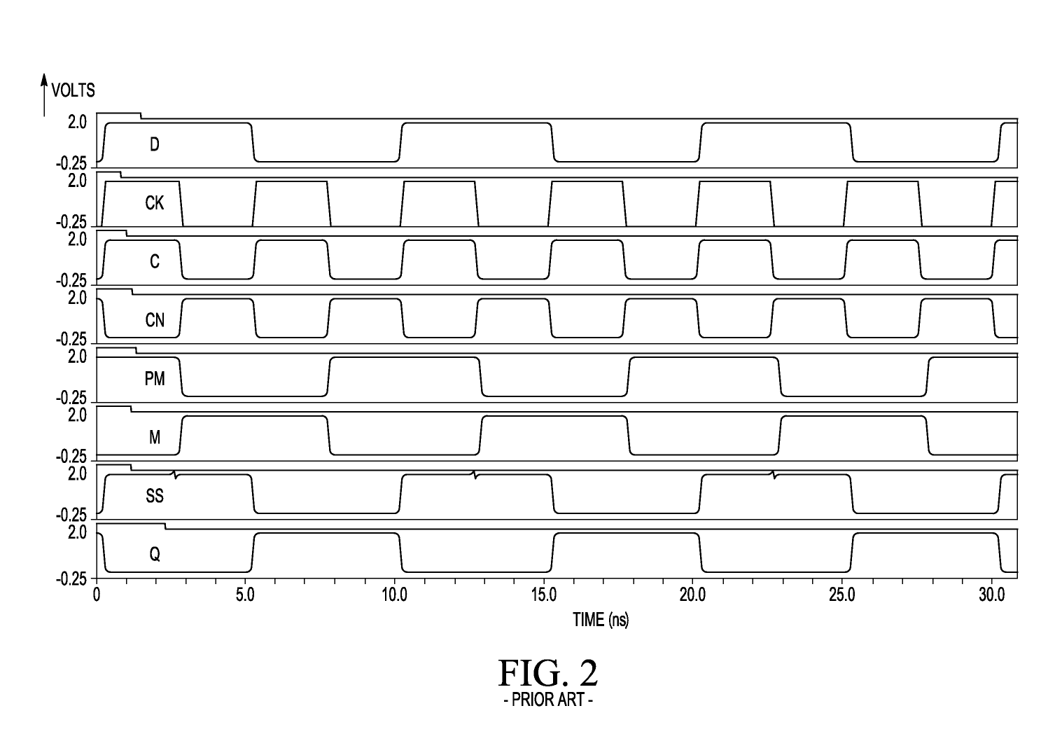

FIG. 2 illustrates signals appearing in operation of an example of the master-slave D flip-flop 100. Immediately before time 0, the data input signal D at the data input terminal 118 was de-asserted (0V) and the data output signal Q at the data output terminal 120 was asserted. The data inverter element devices MP1 and MN4 are ON and the data inverter element devices MN1 and MP4 are OFF. The system clock signal CK was de-asserted (0V in this example) and the clock signals CN and C were respectively asserted (high) and de-asserted. The clock switch elements SP1-SN1 were ON while the clock switch elements SP2-SN2 were OFF and the first three-state inverter stage 108 was ON while the second three-state inverter stage 110 was OFF. The signal PM at the node 122 at the output of the first three-state inverter stages 108 is a function only of the input signal D, which is asserted and the output signal M of the first inverter INV1 and of the master latch 101 at the node 124 is de-asserted.

At time 0, the system clock signal CK is asserted (rises in this example) and the clock signals CN and C are respectively de-asserted (fall to 0V) and asserted. The pairs of clock switch elements SP1-SN1 and SP4-SN4 are turned OFF, turning OFF the first and fourth three-state inverter stages 108 and 114, whose output signals become independent of their input signals. The pairs of clock switch elements SP2-SN2 and SP3-SN3 are turned ON, turning ON the second and third three-state inverter stages 110 and 112. The signals M and PM at the nodes 122 and 124 are maintained during the period while the clock signal C is asserted by the positive feedback of the first inverter INV1 and the second three-state inverter stage 110. The output signal M of the first inverter INV1 and of the master latch 101 at the node 124 is inverted in the third three-state inverter stage 112, so that its output signal SS at the node 126 is asserted, is inverted in the second inverter INV2 and the data output signal Q at the data output terminal 120 is de-asserted. Thus the signal D (0V) is stored in the flip-flop 100 and appears at the output Q of the flip-flop 100 at the rising edge of the system clock CK.

At time 2.5 ns, the clock signals CN and C are respectively asserted and de-asserted. The pairs of clock switch elements SP1-SN1 and SP4-SN4 are turned ON, turning ON the first and fourth three-state inverter stages 108 and 114, whose output signals become functions of their input signals. The data input signal D at the input terminal 118 is inverted by the first three-state inverter stage 108 whose output signal PM at the node 122 de-asserts. The first inverter INV1 inverts the signal PM at the node 122 and its output signal M at the node 124 asserts. The pairs of clock switch elements SP2-SN2 and SP3-SN3 are turned OFF, turning OFF the second and third three-state inverter stages 110 and 112. The signal SS at the node 126 and Q at the data output terminal 120 are maintained during the period while the clock signal C is de-asserted by the positive feedback of the second inverter INV2 and the fourth three-state inverter stage 114.

At time 5 ns, the clock signals CN and C are respectively de-asserted and asserted. The pairs of clock switch elements SP1-SN1 and SP4-SN4 are turned OFF, turning OFF the first and fourth three-state inverter stages 108 and 114, whose outputs become independent of their inputs. Immediately after the time 5 ns, the data input signal D at the data input terminal 118 is de-asserted in this example of operation. The pairs of clock switch elements SP2-SN2 and SP3-SN3 are turned ON, turning ON the second and third three-state inverter stages 110 and 112. The signals M and PM are maintained during the period while the clock signal C is asserted by the positive feedback of the first inverter INV1 and the second three-state inverter stage 110. The output signal M of the first inverter INV1 and of the master latch 101 is inverted in the third three-state inverter stage 112, so that its output signal SS is de-asserted, is inverted in the second inverter INV2 and the data output signal Q at the data output terminal 120 is asserted.

At time 7.5 ns, the clock signals CN and C are respectively asserted and de-asserted. The pairs of clock switch elements SP1-SN1 and SP4-SN4 are turned ON, turning ON the first and fourth three-state inverter stages 108 and 114, whose output signals become functions of their input signals. The de-asserted data input signal D at the input terminal 118 is inverted by the first three-state inverter stage 108 whose output signal PM at the node 122 asserts. The first inverter INV1 inverts the signal PM at the node 122 and its output signal M at the node 124 de-asserts. The pairs of clock switch elements SP2-SN2 and SP3-SN3 are turned OFF, turning OFF the second and third three-state inverter stages 110 and 112. The signals SS at the node 126 and Q at the data output terminal 120 are maintained during the period while the clock signal C is de-asserted by the positive feedback of the second inverter INV2 and the fourth three-state inverter stage 114.

At time 10 ns, the clock signals CN and C are respectively de-asserted and asserted. The pairs of clock switch elements SP1-SN1 and SP4-SN4 are turned OFF, turning OFF the first and fourth three-state inverter stages 108 and 114, whose output signals become independent of their input signals. Immediately after the time 10 ns, the data input signal D at the data input terminal 118 is de-asserted in this example of operation. The cycle repeats with a periodicity of 10 ns, as a function of the data input signal D at the data input terminal 118.

Known approaches to reduce power consumption of a D flip-flop of the kind shown in FIG. 1 tend to be inefficient, and result in more complicated design flow and increased design cycle time and increased die size, often with limited power reduction.

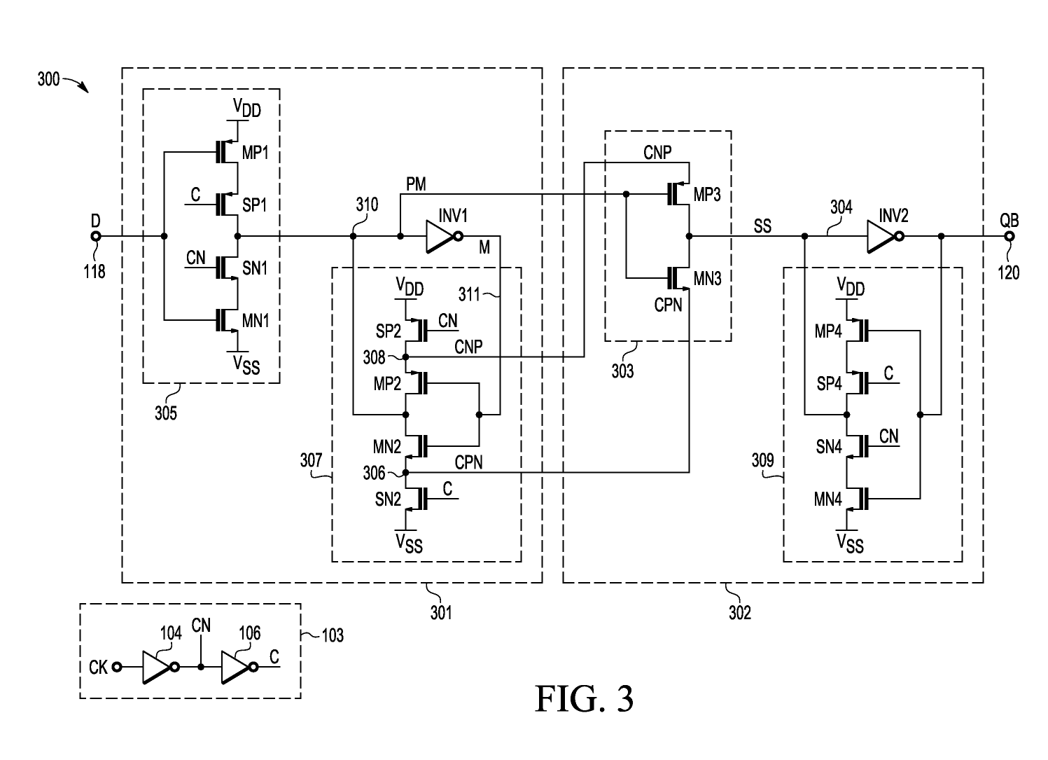

FIGS. 3 to 8 illustrate examples of flip-flops 300, 500 and 700 having a master latch 301, 501 and 701 and a slave latch 302, 502 and 702, and of a method of operating such a flip-flop, in accordance with embodiments of the invention. The illustrated CMOS D flip-flops 300, 500 and 700, have reduced gate and wiring capacitance of clock devices, while ensuring that: (a) the flip-flops 300, 500 and 700 have lower power consumption than the flip-flop 100, (b) the flip-flops 300, 500 and 700 are fully static logic, since static logic is dominant, (c) the performance of the flip-flops 300, 500 and 700 is equal to or better than the flip-flop 100, (d) the size of the flip-flops 300, 500 and 700 is smaller than the flip-flop 100, (e) the flip-flops 300, 500 and 700 present less loading to the external clock tree as the flip-flop 100, and (f) the flip-flops 300, 500 and 700 still permit use of other, additional power reduction techniques.

The master latches 301, 501 and 701 have first and second three-state stages 305, 505 and 705 and 307, 507 and 707 having respectively first and second data inputs, first and second clock inputs and first and second data outputs and a first feedback stage INV1 for positive feedback from the first and second data outputs to the second data input. The slave latches 302, 502 and 702 of the flip-flops 300, 500 and 700 have third and fourth three-state stages 303, 509 and 703 and 309, 503 and 503 having respectively third and fourth data inputs, third and fourth clock inputs and third and fourth data outputs, and a second feedback stage INV2 for positive feedback from the third and fourth data outputs to the fourth data input.

The first data input receives a data input signal D. Output signals at the first and second data outputs are functions of their respective data inputs when the clock signals C at the first and second clock inputs are respectively de-asserted and asserted. The data input of the third three-state stage 303, 509 and 703 receives a data signal from the master latch 301, 501 and 701. Output signals at the third and fourth data outputs are functions of their respective data signals when the clock signals at the third and fourth clock inputs are respectively asserted and de-asserted. One of the first, second, third and fourth three-state stages has a clock switch element which receives clock signals C and CN from a clock signal source 103, provides the clock signals at the clock inputs of the same three-state stage and also provides the clock signals at the clock inputs of a different one of the first, second, third and fourth three-state stages. Sharing the clock switch element between two of the three-state stages in this way enables a reduction in the number of clock switch elements and reduction in power consumption.

In the examples of flip-flops 300, 500 and 700, the master latch or the slave latch includes the clock switch element and the other of the master latch and slave latch includes the different one of the first, second, third and fourth three-state stages. In these examples, the master latch includes the clock switch element and the slave latch includes the different one of the first, second, third and fourth three-state stages.

In the example of the flip-flop 300, the second three-state stage 307 comprises the clock switch element SP2-SN2, which is connected to a power supply V_{DD}-V_{SS}, and a data inverter element MP2-MN2 connected in series with the clock switch element, and the third clock input receives a clock signal CNP-CPN from the clock switch element SP2-SN2 of the second three-state stage 307. The third three-state stage 303 comprises an inverter element MP3-MN3 having a signal path connected to receive the clock signal CNP-CPN from the clock switch element SP2-SN2 of the second three-state stage 307, and a control node connected to the third data input and receiving the data signal PM from an input of the first feedback stage INV1.

In the example of the flip-flop 500, the first three-state stage 505 comprises a clock switch element SP1-SN1, which is connected to a power supply V_{DD}-V_{SS}, and a data inverter element MP1-MN1 connected in series with the clock switch element SP1-SN1, and the fourth clock input receives a clock signal CPP-CNN from the clock switch element SP1-SN1 of the first three-state stage. The fourth three-state stage 503 comprises an inverter element MP4-MN4 having a signal path connected to the fourth clock input to receive the clock signal CPP-CNN from the clock switch element SP1-SN1, and a control node receiving the data signal Q from an output of the second feedback stage INV2.

In the example of the flip-flop 700, the first three-state stage 705 comprises a first clock switch element SP1-SN1, which is connected to a power supply V_{DD}-V_{SS}, and a first data inverter element MP1-MN1 connected in series with the first clock switch element SP1-SN1. The second three-state stage 707 comprises a second data inverter element MP2-MN2, which is connected to a power supply V_{DD}-V_{SS}, and a second clock switch element SP2-SN2 connected in series with the data inverter element MP2-MN2. The third three-state stage 703 comprises a third switch element SP3-SN3 having a signal path receiving its data input signal PS-NS from the second data inverter element MP2-MN2 and a control node receiving the clock signal CN-C from the clock signal source 103. The fourth clock input receives a clock signal from the first clock switch element. The fourth three-state stage has an inverter element having a signal path receiving the clock signal CPP-CNN from the first clock switch element SP1-SN1, and a control node receiving the data signal Q from an output of the second feedback stage INV2.

In the examples of the flip-flops 300, 500 and 700, the first, second, third and fourth three-state stages comprise inverter stages including complementary pairs of semiconductor devices having signal paths connected in series, and control electrodes controlling the signal paths and receiving at least one of the data input signals and the clock signals, and the first and second feedback stages are inverter stages. The complementary pairs of semiconductor devices form the clock switch elements and the data inverter elements. The flip-flops 300, 500 and 700 are D flip-flops although the invention can be adapted to other configurations of flip-flops.

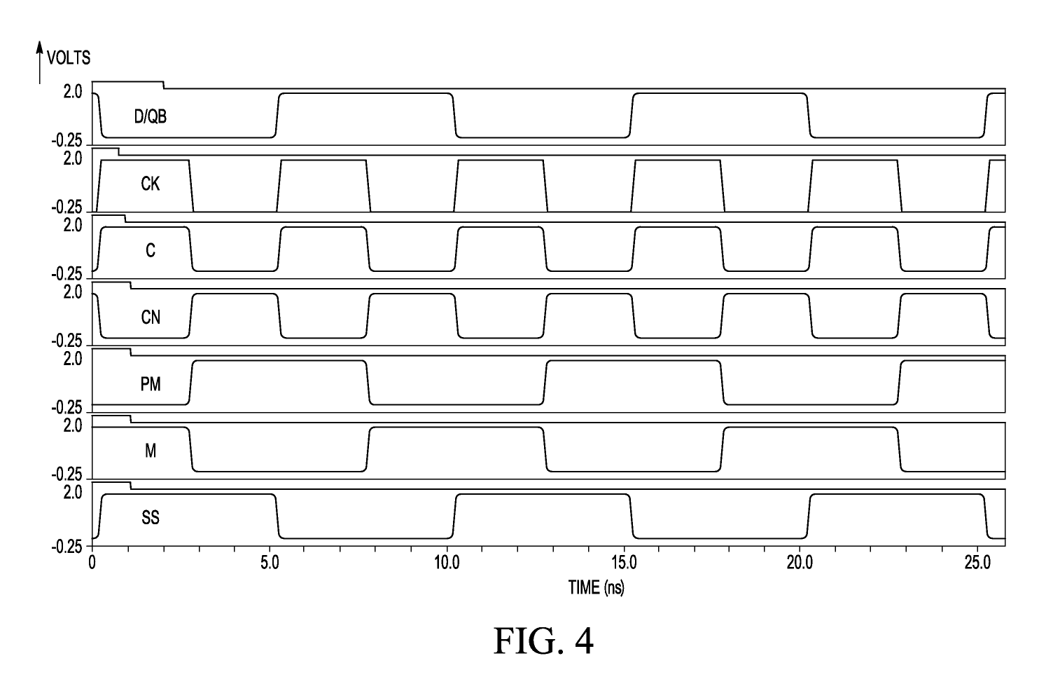

In more detail, referring to FIGS. 3 and 4, the first and fourth three-state inverter stages 305 and 309 of the D flip-flop 300 include pairs of data inverter elements having p-type and n-type CMOS devices MP1-MN1 and MP4-MN4, having signal paths connected to high and low voltage power supplies V_{DD} and V_{SS} and control electrodes connected to receive the respective data input signals of the first and fourth three-state stages 305 and 309. The first and fourth three-state stages 305 and 309 also include pairs of clock switch elements SP1-SN1 and SP4-SN4, having p-type and n-type CMOS devices having signal paths connected in series with each other and in series with the signal paths of the data inverter element devices MP1-MN1 and MP4-MN4. The clock switch elements SP1 and SP4 receive the clock signal C on their control electrodes, whereas the clock switch elements SN1 and SN4 receive the opposite phase clock signal CN on their control electrodes.

The second three-state stage 307 of the D flip-flop 300 includes a pair of clock switch elements SP2-SN2 having p-type and n-type CMOS devices having signal paths connected to high and low voltage power supplies V_{DD} and V_{SS} and control electrodes connected to receive the clock signals CN and C respectively on their control electrodes. The second three-state stage 307 of the D flip-flop 300 also includes a pair of data inverter elements having p-type and n-type CMOS devices MP2-MN2 having signal paths connected in series with each other and in series with the signal paths of the pair of clock switch elements SP2-SN2 and control electrodes connected to receive the data input signal M of the second three-state stage 307 from the output of the first inverter INV1 at a node 311.

The third three-state stage 303 of the D flip-flop 300 includes a pair of data inverter elements having p-type and n-type CMOS devices MP3-MN3, which have signal paths connected in series with each other and to a common node 304. The signal path of the data inverter element MP3 is connected between the node 304 and a node 308 common to the signal paths of the data inverter element MP2 and the clock switch element SP2 to receive a clock signal CNP from the second three-state stage 307. The signal path of the data inverter element MN3 is connected between the node 304 and a node 306 common to the signal paths of the data inverter element MN2 and the clock switch element SN2 to receive a clock signal CPN from the second three-state stage 307. The clock switch elements SP2-SN2 of the second three-state stage 307 are shared with the third three-state stage 303 and no additional clock switch element is needed in the third three-state stage 303 of the D flip-flop 300, unlike the D flip-flop 100, reducing the load that the clock switches and associated wiring present to the clock source 103 and reducing the semiconductor area occupied by the IC.

The output signal PM of the master latch 301 is from a node 310 between the outputs of the first and second three-state stages 305 and 307. The node 310 is common to the signal paths of the clock switch elements SP1-SN1 and of the data inverter elements MP2-MN2 and is connected to the input of the first feedback inverter INV1. Having the output signal PM of the master latch 301 from the input to the first feedback inverter INV1 instead from its output avoids the signal paths of the data inverter elements MP2-MN2 and MP3-MN3 of the second and third three-state stages 307 and 303 shorting the first inverter INV1. The third and fourth three-state stages 303 and 309 provide an output signal SS at the node 304 common to the signal paths of the data inverter elements MP3-MN3 and the signal paths of the clock switch elements SP4-SN4. The output QB of the slave latch 302 and of the D flip-flop 300 appears at the output terminal 120 and is applied to the control electrodes of the data inverter element devices MP4-MN4 to provide the positive feedback of the fourth three-state stage 309.

FIG. 4 illustrates signals appearing in operation of an example of the master-slave D flip-flop 300. Immediately before the time 0, the data input signal D at the data input terminal 118 was asserted (high in this example), the data inverter element devices MP1 and MP4 being OFF and the data inverter element devices MN1 and MN4 being ON. The system clock signal CK was de-asserted (0V) and the clock signals CN and C were respectively asserted (high) and de-asserted. The pair of clock switch elements SP1-SN1 was ON and the first three-state stage 305 was ON. The signal PM at the node 310 at the output of the first three-state stages 305 is de-asserted and the output signal M of the first feedback inverter INV1 and of the master latch 301 at the node 311 is asserted. The data output signal QB at the data output terminal 120 is similar to the data input signal D at all times in this example in this example of a divide-by-two application, where the data output 120 is connected to the data input 118, and is represented by the same timing graph.

At time 0, the system clock signal CK is asserted (rises in this example) and the clock signals CN and C are respectively de-asserted (fall to 0V) and asserted. The pairs of clock switch elements SP1-SN1 and SP4-SN4 are turned OFF, turning OFF the first and fourth three-state stages 305 and 309, whose output signals become independent of their input signals. The pair of clock switch elements SP2-SN2 is turned ON, turning ON the second three-state stage 307. Turning ON the pair of clock switch elements SP2-SN2 also asserts the clock signal CNP at the node 308 and de-asserts the clock signal CPN at the node 306, applied to the signal paths of the data inverter element devices MP3-MN3 of the third three-state stage 303. The signals M and PM at the nodes 310 and 311 are maintained during the period while the clock signal C is asserted by the positive feedback of the first feedback inverter INV1 and the second three-state stage 307. The output signal PM of the second three-state stage 307 and of the master latch 301 at the node 310 turns ON the data inverter element device MP3 and turns OFF the data inverter element device MN3 so that the signal PM is inverted in the third three-state stage 303 and its output signal SS at the node 304 is asserted, is inverted in the second feedback inverter INV2 and the data output signal QB at the data output terminal 120 is de-asserted.

At time 2.5 ns, the clock signals CN and C are respectively asserted and de-asserted. The pairs of clock switch elements SP1-SN1 and SP4-SN4 are turned ON, turning ON the first and fourth three-state stages 305 and 309, whose output signals become functions of their input signals. The data input signal D at the input terminal 118 is inverted by the first three-state stage 305 whose output signal PM at the node 310 asserts. The first feedback inverter INV1 inverts the signal PM at the node 310 and its output signal M at the node 311 de-asserts. The pair of clock switch elements SP2-SN2 is turned OFF, turning OFF the second three-state stage 307 and turning OFF the signal paths of the data inverter element devices MP3-MN3 of the third three-state stage 303. The signal SS at the node 304 and QB at the data output terminal 120 are maintained during the period while the clock signal C is de-asserted by the positive feedback of the second feedback inverter INV2 and the fourth three-state stage 309.

At time 5 ns, the clock signals CN and C are respectively de-asserted and asserted. The pairs of clock switch elements SP1-SN1 and SP4-SN4 are turned OFF, turning OFF the first and fourth three-state stages 305 and 309, whose outputs become independent of their inputs. Immediately after the time 5 ns, the data input signal D at the data input terminal 118 is asserted in this example of operation. The pair of clock switch elements SP2-SN2 is turned ON, turning ON the second three-state stages 307. Turning ON the pair of clock switch elements SP2-SN2 also de-asserts the clock signal CPN at the node 306 and asserts the clock signal CNP at the node 308, applied to the signal paths of the data inverter element devices MP3-MN3 of the third three-state stage 303. The signals M and PM are maintained during the period while the clock signal C is asserted by the positive feedback of the first feedback inverter INV1 and the second three-state stage 307. The output signal PM at the node 310 of the second three-state stage 307 and of the master latch 301 turns OFF the data inverter element device MP3 and turns ON the data inverter element device MN3 so that the signal PM is inverted in the third three-state stage 303 and its output signal SS at the node 304 is de-asserted, is inverted in the second feedback inverter INV2 and the data output signal QB at the data output terminal 120 is asserted

At time 7.5 ns, the clock signals CN and C are respectively asserted and de-asserted. The pairs of clock switch elements SP1-SN1 and SP4-SN4 are turned ON, turning ON the first and fourth three-state stages 305 and 309, whose output signals become functions of their input signals. The asserted data input signal D at the input terminal 118 is inverted by the first three-state stage 305 whose output signal PM at the node 310 de-asserts. The first feedback inverter INV1 inverts the signal PM and its output signal M at the node 311 asserts. The pair of clock switch elements SP2-SN2 is turned OFF, turning OFF the second three-state stage 307 and turning OFF the signal paths of the data inverter element devices MP3-MN3 of the third three-state stage 303. The signal SS at the node 304 and QB at the data output terminal 120 are maintained during the period while the clock signal C is de-asserted by the positive feedback of the second feedback inverter INV2 and the fourth three-state stage 309.

At time 10 ns, the clock signals CN and C are respectively de-asserted and asserted. The pairs of clock switch elements SP1-SN1 and SP4-SN4 are turned OFF, turning OFF the first and fourth three-state stages 305 and 309, whose output signals become independent of their input signals. Immediately after the time 10 ns, the data input signal D at the data input terminal 118 is de-asserted in this example of operation. The cycle repeats with a periodicity of 10 ns, as a function of the data input signal D at the data input terminal 118.

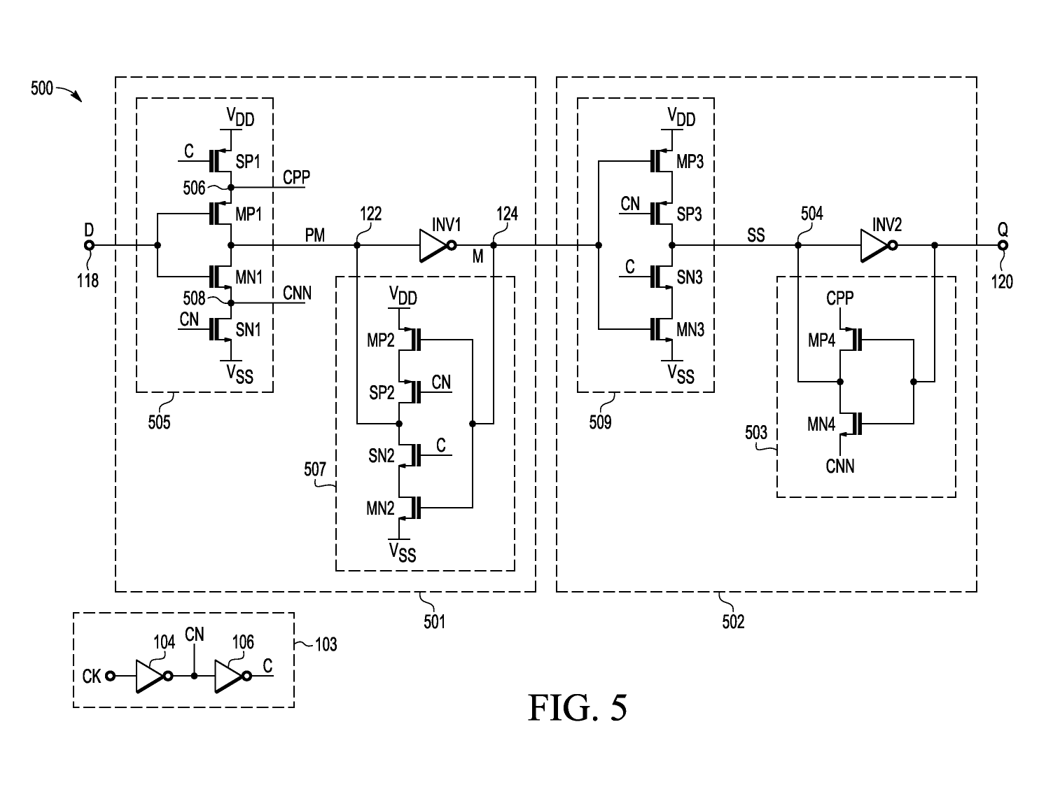

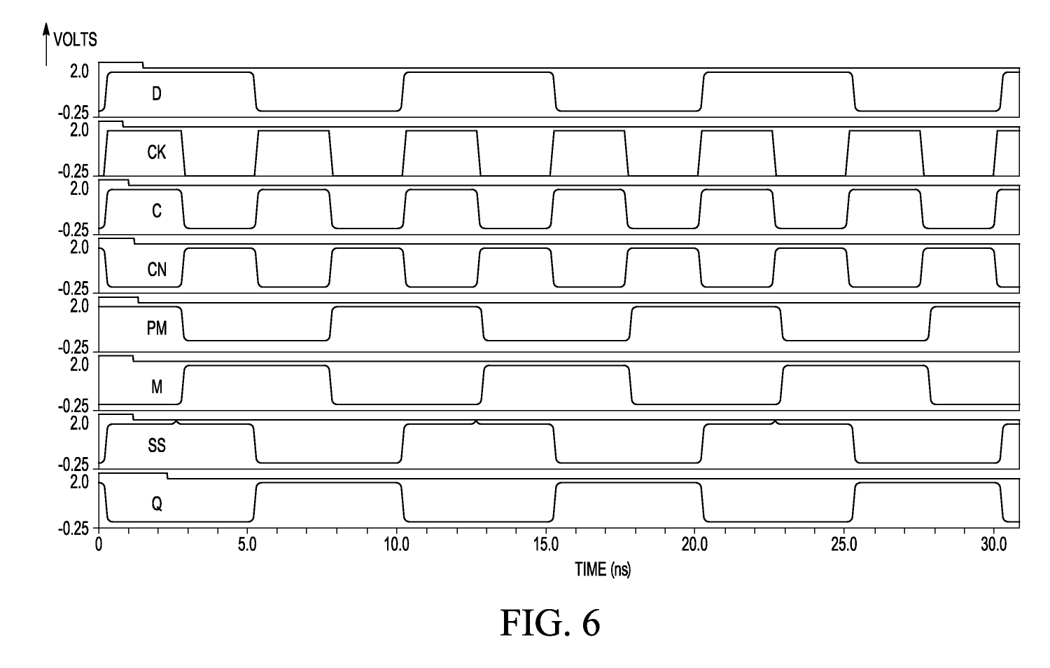

Referring now to FIGS. 5 and 6, in the D flip-flop 500 the first three-state stage 505 includes a pair of clock switch elements SP1-SN1 having p-type and n-type CMOS devices having signal paths connected to high and low voltage power supplies V_{DD} and V_{SS} and control electrodes connected to receive the clock signals C and CN respectively on their control electrodes. The first three-state stage 505 of the D flip-flop 500 also includes a pair of data inverter elements having p-type and n-type CMOS devices MP1-MN1 having signal paths connected in series with each other and in series with the signal paths of the pair of clock switch elements SP1-SN1 and control electrodes connected to receive the data input signal D of the first three-state stage 505 and of the master latch 501 from the input terminal 118.

The second and third three-state stages 507 and 509 of the D flip-flop 500 include pairs of data inverter elements having p-type and n-type CMOS devices MP2-MN2 and MP3-MN3, having signal paths connected to high and low voltage power supplies V_{DD} and V_{SS} and control electrodes connected to receive the respective data input signals of the second and third three-state stages 507 and 509. The second and third three-state stages 507 and 509 also include pairs of clock switch elements SP2-SN2 and SP3-SN3, having p-type and n-type CMOS devices having signal paths connected in series with each other and in series with the signal paths of the data inverter element devices MP2-MN2 and MP3-MN3. The clock switch elements SP2 and SP3 receive the clock signals CN on their control electrodes, whereas the clock switch elements SN2 and SN3 receive the opposite phase clock signals C on their control electrodes.

The fourth three-state stage 503 of the D flip-flop 500 includes a pair of data inverter elements having p-type and n-type CMOS devices MP4-MN4, having signal paths connected in series with each other and to a common node 504. The signal path of the data inverter element MP4 is connected between the node 504 and a node 506 common to the signal paths of the data inverter element MP1 and the clock switch element SP1 to receive a clock signal CPP from the first three-state stage 505. The signal path of the data inverter element MN4 is connected between the node 504 and a node 508 common to the signal paths of the data inverter element MN1 and the clock switch element SN1 to receive a clock signal CNN from the first three-state stage 505. The clock switch elements SP1-SN1 of the first three-state stage 505 are shared with the fourth three-state stage 503 and no additional clock switch element in the fourth three-state stage 503 of the D flip-flop 500, unlike the D flip-flop 100, reducing the load that the clock switches and associated wiring present to the clock source 103 and reducing the semiconductor area occupied by the IC.

The output signal PM of the first and second three-state stages 505 and 507 appears at a node 122 connected to the signal paths of the data inverter elements MP1-MN1 and of the clock switch elements SP2-SN2 and connected to the input of the first feedback inverter INV1. The data input signal of the third three-state stage 509 is provided by the output signal M of the master latch 501 at the output of the first feedback inverter INV1 at a node 124. The third and fourth three-state stages 509 and 503 provide an output signal SS at the node 504 connected to the signal paths of the clock switch elements SP3-SN3 and of the data inverter elements MP4-MN4 and to the input of the second feedback inverter INV2. The output Q at the output of the slave latch 502 and of the D flip-flop 500 at the output terminal 120 is applied to the control electrodes of the data inverter element devices MP4-MN4 to provide the positive feedback of the fourth three-state stage 503.

FIG. 6 illustrates signals appearing in operation of an example of the master-slave D flip-flop 500. Immediately before the time 0, the data input signal D at the data input terminal 118 was de-asserted (0V), the data inverter element device MP1 being ON and the data inverter element device MN1 being OFF. The system clock signal CK was de-asserted (0V in this example) and the clock signals CN and C were respectively asserted (high) and de-asserted. The pair of clock switch elements SP1-SN1 was ON and the first three-state stage 505 was ON. The signal PM at the node 122 at the output of the first three-state stage 505 is asserted and the output signal M of the first feedback inverter INV1 and of the master latch 501 at the node 124 is de-asserted.

At time 0, the system clock signal CK is asserted (rises in this example) and the clock signals CN and C are respectively de-asserted (fall to 0V) and asserted. The pair of clock switch elements SP1-SN1 is turned OFF, turning OFF the first three-state stage 505, whose output signal becomes independent of its input signals. The pairs of clock switch elements SP2-SN2 and SP3-SN3 are turned ON, turning ON the second and third three-state stages 507 and 509, whose output signals become functions of their input signals. Turning OFF the pair of clock switch elements SP1-SN1 also de-asserts the clock signal CPP at the node 506 and asserts the clock signal CNN at the node 508, applied to the signal paths of the data inverter element devices MP4-MN4 of the fourth three-state stage 503, which are turned OFF. The signals M and PM at the nodes 122 and 124 are maintained during the period while the clock signal C is asserted by the positive feedback of the first feedback inverter INV1 and the second three-state stage 507. The output signal M of the first feedback inverter INV1 and of the master latch 501 at the node 124 is inverted in the third three-state stage 509 when it turns ON, so that its output signal SS at the node 504 is asserted, is inverted in the second feedback inverter INV2 and the data output signal Q at the data output terminal 120 is de-asserted.

At time 2.5 ns, the clock signals CN and C are respectively asserted and de-asserted. The pair of clock switch elements SP1-SN1 is turned ON, turning ON the first three-state stage 505, whose output signals become a function of its input signals. The pairs of clock switch elements SP2-SN2 and SP3-SN3 are turned OFF, turning OFF the second and third three-state stages 507 and 509, whose output signals become independent of their input signals. The data input signal D at the input terminal 118 is inverted by the first three-state stage 505 turning ON and its output signal PM at the node 122 de-asserts. The first feedback inverter INV1 inverts the signal PM at the node 122 and its output signal M at the node 124 asserts. Turning ON the pair of clock switch elements SP1-SN1 also asserts the clock signal CPP at the node 506 and de-asserts the clock signal CNN at the node 508, applied to the signal paths of the data inverter element devices MP4-MN4 of the fourth three-state stage 503. The signals SS at the node 504 and Q at the data output terminal 120 are maintained during the period while the clock signal C is de-asserted by the positive feedback of the second feedback inverter INV2, whose de-asserted output signal Q turns ON the data inverter element device MP4 of the fourth three-state stage 503.

At time 5 ns, the clock signals CN and C are respectively de-asserted and asserted. The pair of clock switch elements SP1-SN1 is turned OFF, turning OFF the first three-state stage 505, whose output becomes independent of its inputs. The pairs of clock switch elements SP2-SN2 and SP3-SN3 are turned ON, turning ON the second and third three-state stages 507 and 509, whose outputs become functions of their inputs. Immediately after the time 5 ns, the data input signal D at the data input terminal 118 is de-asserted in this example of operation. The signals M and PM are maintained during the period while the clock signal C is asserted by the positive feedback of the first feedback inverter INV1 and the second three-state stage 507. Turning OFF the pair of clock switch elements SP1-SN1 also de-asserts the clock signal CPP at the node 506 and asserts the clock signal CNN at the node 508, applied to the signal paths of the data inverter element devices MP4-MN4 of the fourth three-state stage 503, which are turned OFF. The output signal M of the first feedback inverter INV1 and of the master latch 501 is inverted in the third three-state stage 509, so that its output signal SS is de-asserted, is inverted in the second feedback inverter INV2 and the data output signal Q at the data output terminal 120 is asserted.

At time 7.5 ns, the clock signals CN and C are respectively asserted and de-asserted. The pair of clock switch elements SP1-SN1 is turned ON, turning ON the first three-state stage 505, whose output signals become a function of its input signals. The pairs of clock switch elements SP2-SN2 and SP3-SN3 are turned OFF, turning OFF the second and third three-state stages 507 and 509, whose output signals become independent of their input signals. The de-asserted data input signal D at the input terminal 118 is inverted by the first three-state stage 505 whose output signal PM at the node 122 asserts. The first feedback inverter INV1 inverts the signal PM at the node 122 and its output signal M at the node 124 de-asserts. Turning ON the pair of clock switch elements SP1-SN1 also asserts the clock signal CPP at the node 506 and de-asserts the clock signal CNN at the node 508, applied to the signal paths of the data inverter element devices MP4-MN4 of the fourth three-state stage 503. The signals SS at the node 504 and Q at the data output terminal 120 are maintained during the period while the clock signal C is de-asserted by the positive feedback of the second feedback inverter INV2, whose asserted output signal Q turns ON the data inverter element device MN4 of the fourth three-state stage 503.

At time 10 ns, the clock signals CN and C are respectively de-asserted and asserted. The pair of clock switch elements SP1-SN1 is turned OFF, turning OFF the first three-state stage 505, whose output becomes independent of its inputs. The pairs of clock switch elements SP2-SN2 and SP3-SN3 are turned ON, turning ON the second and third three-state stages 507 and 509, whose outputs become functions of their inputs. Immediately after the time 10 ns, the data input signal D at the data input terminal 118 is asserted in this example of operation. The cycle repeats with a periodicity of 10 ns, as a function of the data input signal D at the data input terminal 118.

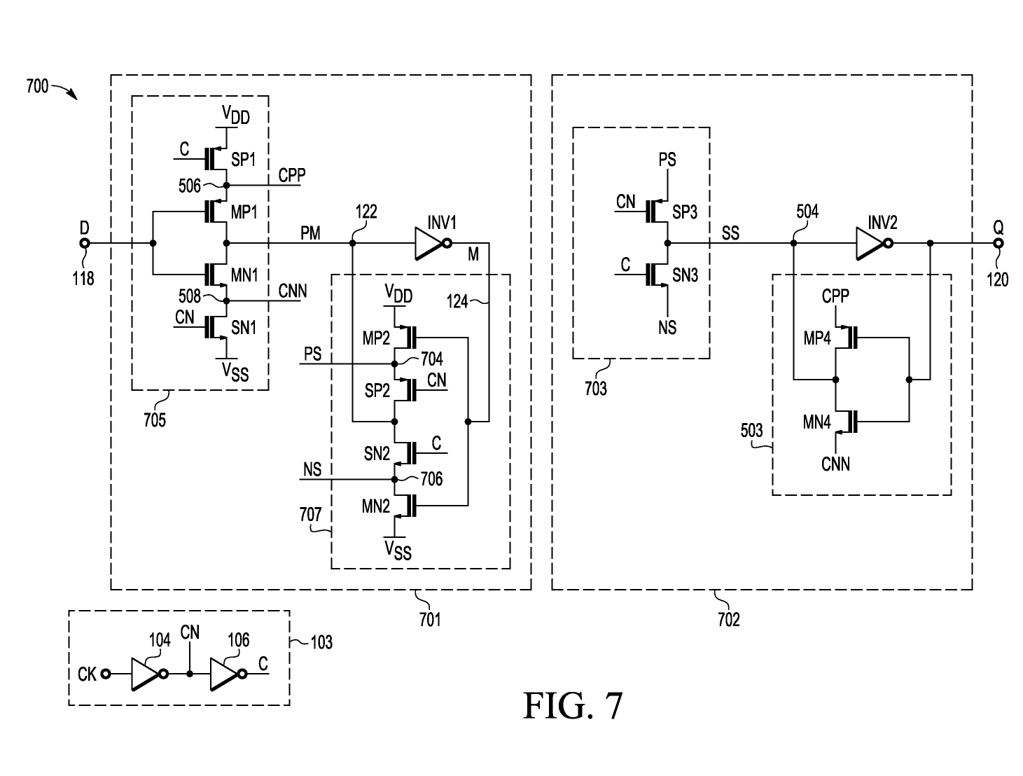

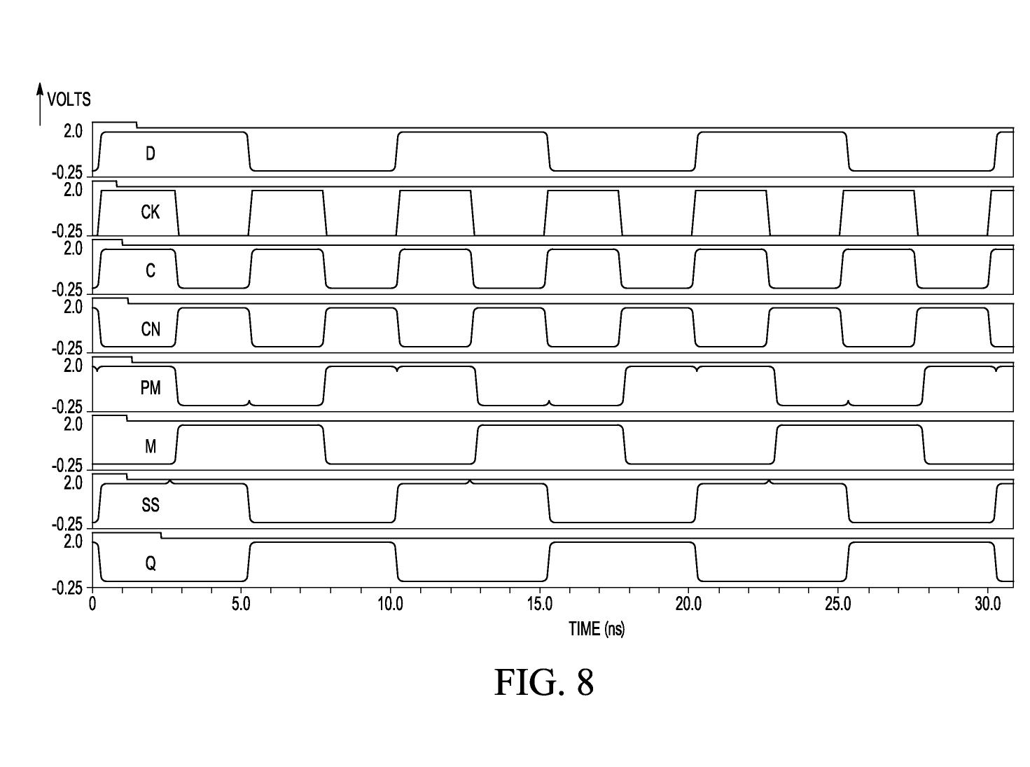

Referring now to FIGS. 7 and 8, in the D flip-flop 700 the first three-state stage 705 includes a pair of clock switch elements SP1-SN1 having p-type and n-type CMOS devices having signal paths connected to high and low voltage power supplies V_{DD} and V_{SS} and control electrodes connected to receive the clock signals C and CN respectively on their control electrodes. The first three-state stage 705 of the D flip-flop 700 also includes a pair of data inverter elements having p-type and n-type CMOS devices MP1-MN1 having signal paths connected in series with each other and in series with the signal paths of the pair of clock switch elements SP1-SN1 and control electrodes connected to receive the data input signal D of the first three-state stage 705 and of the master latch 701 from the input terminal 118.

The second three-state stage 707 of the D flip-flop 700 includes a pair of data inverter elements having p-type and n-type CMOS devices MP2-MN2, having signal paths connected to high and low voltage power supplies V_{DD} and V_{SS} and control electrodes connected to receive the data input signals of the second three-state stage 707. The second three-state stage 707 also includes a pair of clock switch elements, having p-type and n-type CMOS devices SP2-SN2 having signal paths connected in series with each other and in series with the signal paths of the data inverter element devices MP2-MN2. The clock switch elements SP2 and SN2 receive the clock signals CN and C on their control electrodes, respectively.

The third three-state stage 703 has a pair of switch elements having p-type and n-type CMOS devices SP3-SN3 having signal paths connected in series with each other and to a common node 504. The switch elements SP3 and SN3 receive the clock signals CN and C on their control electrodes, respectively. The signal path of the switch element SP3 is connected between the node 504 and a node 704 common to the signal paths of the data inverter element MP2 and the clock switch element SP2 to receive a data signal PS from the second three-state stage 707. The signal path of the switch element SN3 is connected between the node 504 and a node 706 common to the signal paths of the data inverter element MN2 and the clock switch element SN2 to receive a data signal NS from the second three-state stage 707. The data inverter elements MP2-MN2 of the second three-state stage 705 are shared with the third three-state stage 703 and no additional data inverter element is needed in the third three-state stage 703 of the D flip-flop 700, unlike the D flip-flop 100, reducing the semiconductor area occupied by the IC.

The fourth three-state stage 503 of the D flip-flop 700 includes a pair of data inverter elements having p-type and n-type CMOS devices MP4-MN4, having signal paths connected in series with each other and to a common node 504. The signal path of the data inverter element MP4 is connected between the node 504 and a node 506 common to the signal paths of the data inverter element MP1 and the clock switch element SP1 to receive a clock signal CPP from the first three-state stage 705. The signal path of the data inverter element MN4 is connected between the node 504 and a node 508 common to the signal paths of the data inverter element MN1 and the clock switch element SN1 to receive a clock signal CNN from the first three-state stage 705. The clock switch elements SP1-SN1 of the first three-state stage 705 are shared with the fourth three-state stage 503 and no additional clock switch element in the fourth three-state stage 503 of the D flip-flop 700, unlike the D flip-flop 100, reducing the load that the clock switches and associated wiring present to the clock source 103 and reducing the semiconductor area occupied by the IC.

The output signal PM of the first and second three-state stages 705 and 707 appears at a node 122 connected to the signal paths of the data inverter elements MP1-MN1 and of the clock switch elements SP2-SN2 and connected to the input of the first feedback inverter INV1. The output of the first feedback inverter INV1 is connected to the control electrodes of the data inverter elements MP2-MN2 at a node 124 and provides the output signals PS and NS of the second three-state stage 707 and of the master latch 701 as the data input signals for the third three-state stage 703. The third and fourth three-state stages 703 and 503 provide an output signal SS at the node 504 connected to the signal paths of the switch elements SP3-SN3 and of the data inverter elements MP4-MN4 and to the input of the second feedback inverter INV2. The output Q at the output of the slave latch 702 and of the D flip-flop 700 at the output terminal 120 is applied to the control electrodes of the data inverter element devices MP4-MN4 to provide the positive feedback of the fourth three-state stage 503.

FIG. 8 illustrates signals appearing in operation of an example of the master-slave D flip-flop 700. Immediately before the time 0, the data input signal D at the data input terminal 118 was de-asserted (0V), the data inverter element device MP1 being ON and the data inverter element device MN1 being OFF. The system clock signal CK was de-asserted (0V in this example) and the clock signals CN and C were respectively asserted (high) and de-asserted. The pair of clock switch elements SP1-SN1 was ON and the first three-state stage 705 was ON. The signal PM at the node 122 at the output of the first three-state stages 705 is asserted and the output signal M of the first feedback inverter INV1 and of the master latch 701 at the node 124 is de-asserted.

At time 0, the system clock signal CK is asserted (rises in this example) and the clock signals CN and C are respectively de-asserted (fall to 0V) and asserted. The pair of clock switch elements SP1-SN1 is turned OFF, turning OFF the first three-state stage 705, whose output signal becomes independent of its input signals. The pairs of switch elements SP2-SN2 and SP3-SN3 are turned ON, turning ON the second and third three-state stages 707 and 703, whose output signals become functions of their input signals. The de-asserted output signal M of the first feedback inverter INV1 turns the data inverter element devices MP2-MN2 of the second three-state stage 707 respectively ON and OFF, asserting both the data signals PS and NS at the outputs of the master latch 701 and at the nodes 704 and 706 connected to the signal paths of the pairs of switch elements SP3-SN3, and the switch element SP3 asserts the output signal SS at the node 504 The signal SS is inverted in the second feedback inverter INV2 and the data output signal Q at the data output terminal 120 is de-asserted. The signals M and PM at the nodes 122 and 124 are maintained during the period while the clock signal C is asserted by the positive feedback of the first feedback inverter INV1 and the second three-state stage 707.

Turning OFF the pair of clock switch elements SP1-SN1 also de-asserts the clock signal CPP at the node 506 and asserts the clock signal CNN at the node 508, applied to the signal paths of the data inverter element devices MP4-MN4 of the fourth three-state stage 503, which are turned OFF. Accordingly, the data inverter element devices MP4-MN4 do not apply feedback voltage from the second feedback inverter INV2 to the third three-state stage 703 while the clock signals CPP and CNN are respectively de-asserted and asserted.

At time 2.5 ns, the clock signals CN and C are respectively asserted and de-asserted. The pair of clock switch elements SP1-SN1 is turned ON, turning ON the first three-state stage 705, whose output signals become a function of its input signals. The pair of clock switch elements SP2-SN2 is turned OFF, turning OFF the second three-state stage 707, whose output signal becomes independent of its input signal. The data input signal D at the input terminal 118 is inverted by the first three-state stage 705 turning ON and its output signal PM at the node 122 de-asserts. The first feedback inverter INV1 inverts the signal PM at the node 122 and its output signal M at the node 124 asserts. The asserted output signal M of the first feedback inverter INV1 turns the data inverter element devices MP2-MN2 of the second three-state stage 707 respectively OFF and ON, de-asserting both the data signals PS and NS at the outputs of the master latch 701 and at the nodes 704 and 706 connected to the signal paths of the pairs of switch elements SP3-SN3, which are both turned OFF, since the clock signal C at the control electrode of the switch element SN3 is de-asserted. The output signal SS at the node 504 becomes independent of the state of the third three-state stage 703.

Turning ON the pair of clock switch elements SP1-SN1 also asserts the clock signal CPP at the node 506 and de-asserts the clock signal CNN at the node 508, applied to the signal paths of the data inverter element devices MP4-MN4 of the fourth three-state stage 503. The signals SS at the node 504 and Q at the data output terminal 120 are maintained during the period while the clock signal C is de-asserted by the positive feedback of the second feedback inverter INV2, whose de-asserted output signal Q turns ON the data inverter element device MP4 of the fourth three-state stage 503.

At time 5 ns, the clock signals CN and C are respectively de-asserted and asserted. The pair of clock switch elements SP1-SN1 is turned OFF, turning OFF the first three-state stage 705, whose output becomes independent of its inputs. The pair of clock switch elements SP2-SN2 is turned ON, turning ON the second three-state stage 707, whose output signal becomes functions of its input signals. Immediately after the time 5 ns, the data input signal D at the data input terminal 118 is de-asserted in this example of operation. The asserted output signal M of the first feedback inverter INV1 turns the data inverter element devices MP2-MN2 of the second three-state stage 707 respectively OFF and ON, de-asserting both the data signals PS and NS at the outputs of the master latch 701 and at the nodes 704 and 706 connected to the signal paths of the pairs of switch elements SP3-SN3, which are turned respectively OFF and ON. The output signal SS at the node 504 is de-asserted, is inverted in the second feedback inverter INV2 and the data output signal Q at the data output terminal 120 is asserted. The signals M and PM are maintained during the period while the clock signal C is asserted by the positive feedback of the first feedback inverter INV1 and the second three-state stage 707.

Turning OFF the pair of clock switch elements SP1-SN1 also de-asserts the clock signal CPP at the node 506 and asserts the clock signal CNN at the node 508, applied to the signal paths of the data inverter element devices MP4-MN4 of the fourth three-state stage 503, which are turned OFF. Accordingly, the data inverter element devices MP4-MN4 do not apply feedback voltage from the second feedback inverter INV2 to the third three-state stage 703 while the clock signals CPP and CNN are respectively de-asserted and asserted.

At time 7.5 ns, the clock signals CN and C are respectively asserted and de-asserted. The pair of clock switch elements SP1-SN1 is turned ON, turning ON the first three-state stage 705, whose output signals become a function of its input signals. The pair of clock switch elements SP2-SN2 is turned OFF, turning OFF the second three-state stage 707, whose output signal becomes independent of its input signal. The de-asserted data input signal D at the input terminal 118 is inverted by the first three-state stage 705 turning ON and its output signal PM at the node 122 asserts. The first feedback inverter INV1 inverts the signal PM at the node 122 and its output signal M at the node 124 de-asserts. The de-asserted output signal M of the first feedback inverter INV1 turns the data inverter element devices MP2-MN2 of the second three-state stage 707 respectively ON and OFF, asserting both the data signals PS and NS at the outputs of the master latch 701 and at the nodes 704 and 706 connected to the signal paths of the pairs of switch elements SP3-SN3, which are both turned OFF, since the clock signal C at the control electrode of the switch element SP3 is de-asserted. The output signal SS at the node 504 becomes independent of the data signals PS and NS at the inputs of the third three-state stage 703.

Turning ON the pair of clock switch elements SP1-SN1 also asserts the clock signal CPP at the node 506 and de-asserts the clock signal CNN at the node 508, applied to the signal paths of the data inverter devices MP4-MN4 of the fourth three-state stage 503. The signals SS at the node 504 and Q at the data output terminal 120 are maintained during the period while the clock signal C is de-asserted by the positive feedback of the second feedback inverter INV2, whose asserted output signal Q turns ON the data inverter element device MN4 of the fourth three-state stage 503.

At time 10 ns, the clock signals CN and C are respectively de-asserted and asserted. The pair of clock switch elements SP1-SN1 is turned OFF, turning OFF the first three-state stage 705, whose output becomes independent of its inputs. The pair of clock switch elements SP2-SN2 is turned ON, turning ON the second three-state stage 707, whose outputs becomes functions of their inputs. Immediately after time 10 ns, the data input signal D at the data input terminal 118 is asserted (in this example of operation). The cycle repeats with a periodicity of 10 ns, as a function of the data input signal D at the data input terminal 118.

Compared to the conventional flip-flop 100, which has four pairs of clock switch elements in addition to four pairs of data inverters, the flip-flops 300, 500 and 700 require only three pairs of clock switch elements. This means the size of clock inverters 104 and 106 of the clock source 103 in the flip-flops 300, 500 and 700 can be linearly reduced by 25%. Additionally, the flip-flop 700 further reduces the number of elements since it eliminates the data inverters MP3 and MN3. The reduced clock switch element loading and reduced size of the clock inverters 104 and 106 reduces the clock power consumption of flip-flops 300 and 500 by about 10% to 25%, while the clock power consumption of the flip-flop 700 is reduced further. The reduced clock inverter 104 presents 25% less loading to external clock tree and 25% reduction of clock tree power consumption. In examples of the flip-flops 100, 300, 500 and 700 having the same types and sizes of transistors, the flip-flops 300 and 500 have 18% less clock power consumption, and the flip-flop 700 has 21% less clock power consumption. The output signal delay times of the flip-flops 300 and 500 has a very small increase, while the output signal delay times of the flip-flop 700 is reduced by about 8%. The combined set-up plus hold times of the flip-flops 300, 500 and 700 is reduced by about 5%.

The reductions in number of clock switch elements and in clock power consumption can readily be applied in different D flip-flop applications, without penalties in the form of design flow complexity, cycle time, die size overhead, or difficulties in time closure.

In the foregoing specification, the invention has been described with reference to specific examples of embodiments of the invention. It will, however, be evident that various modifications and changes may be made therein without departing from the broader spirit and scope of the invention as set forth in the appended claims.

The connections as discussed herein may be any type of connection suitable to transfer signals from or to the respective nodes, units or devices, for example via intermediate devices. Accordingly, unless implied or stated otherwise, the connections may be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice versa. Also, a plurality of connections may be replaced with a single connection that transfers multiple signals serially or in a time multiplexed manner. Likewise, single connections carrying multiple signals may be separated into various different connections carrying subsets of these signals. Therefore, many options exist for transferring signals.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein can be designed as either negative or positive logic signals. Therefore, in alternate embodiments, those signals described as positive logic signals may be implemented as negative logic signals, and those signals described as negative logic signals may be implemented as positive logic signals.

The terms “assert” or “set” and “negate” (or “deassert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures can be implemented which achieve the same functionality. Similarly, any arrangement of components to achieve the same functionality is effectively “associated” such that the desired functionality is achieved. Hence, any two components combined to achieve a particular functionality can be seen as “associated with” each other such that the desired functionality is achieved, irrespective of architectures or intermediate components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

In the claims, the words ‘comprising’ or ‘having’ do not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements.

1. A D flip-flop, comprising:
a master latch having first and second three-state stages having respective first and second data inputs, first and second clock inputs and first and second data outputs, and a first feedback stage for positive feedback from said first and second data outputs to said second data input; and
a slave latch having third and fourth three-state stages having respective third and fourth data inputs, third and fourth clock inputs and third and fourth data outputs, and a second feedback stage for positive feedback from said third and fourth data outputs to said fourth data input;
wherein said first data input receives a data input signal, and output signals at said first and second data outputs are functions of their respective data input signals when clock signals at said first and second clock inputs are respectively de-asserted and asserted;
wherein said third data input receives a data signal from said master latch, and output signals at said third and fourth data outputs are functions of their respective data signals when said clock signals at said third and fourth clock inputs are respectively asserted and de-asserted; and
wherein one of said first, second, third and fourth three-state stages has a clock switch element that receives clock signals from a clock signal source, provides said clock signals at said clock inputs of the same three-state stage and also provides said clock signals at said clock inputs of a different one of said first, second, third and fourth three-state stages.

2. The D flip-flop of claim 1, wherein said first, second, third and fourth three-state stages comprise inverter stages including complementary pairs of semiconductor devices having signal paths connected in series and control electrodes for controlling said signal paths and connected with at least one of said data inputs and said clock inputs, and said first and second feedback stages comprise inverter stages.

3. The D flip-flop of claim 1, wherein one of said master latch and slave latch includes said clock switch element and the other of said master latch and slave latch includes said different one of said first, second, third and fourth three-state stages.

4. The D flip-flop of claim 3, wherein said master latch includes said clock switch element and said slave latch includes said different one of said first, second, third and fourth three-state stages.

5. The D flip-flop of claim 1, wherein said second three-state stage comprises said clock switch element, which is connected to a power supply, and a data inverter connected in series with said clock switch element, and said third clock input is connected to receive said clock signal from said clock switch element of said second three-state stage.

6. The D flip-flop of claim 5, wherein said third three-state stage comprises an inverter having a signal path connected to said clock switch element of said second three-state stage, and a control node connected to said third data input to receive said data signal from an input of said first feedback stage.

7. The D flip-flop of claim 1, wherein said first three-state stage comprises said clock switch element, which is connected to a power supply, and a data inverter connected in series with said clock switch element, and said fourth clock input is connected to receive said clock signal from said clock switch element of said first three-state stage.

8. The D flip-flop of claim 7, wherein said fourth three-state stage comprises an inverter having a signal path connected to said clock switch element of said first three-state stage, and a control node connected to said fourth data input to receive said data signal from an output of said second feedback stage.

9. The D flip-flop of claim 1, wherein said first three-state stage has a first clock switch element connected to a power supply and a first data inverter connected in series with said first clock switch element, said second three-state stage has a second data inverter connected to a power supply and a second clock switch element connected in series with said second data inverter, said third three-state stage has a third switch element having a signal path connected to said second data inverter and a control node connected to receive said clock signal from said clock signal source, and said fourth clock input is connected to receive said clock signal from said first clock switch element.

10. The D flip-flop of claim 9, wherein said fourth three-state stage comprises an inverter having a signal path connected to said first clock switch element, and a control node connected to receive said data signal from an output of said second feedback stage.

11. A method of operating a D flip-flop comprising a master latch and a slave latch, said master latch comprising first and second three-state stages having respective first and second data inputs, first and second clock inputs and first and second data outputs, and a first feedback stage for positive feedback from said first and second data outputs to said second data input; said slave latch comprising third and fourth three-state stages having respective third and fourth data inputs, third and fourth clock inputs and third and fourth data outputs, and a second feedback stage for positive feedback from said third and fourth data outputs to said fourth data input, the method comprising:
applying a data input signal to said first data input, output signals at said first and second data outputs being functions of their respective data input signals when said clock signals at said first and second clock inputs are respectively de-asserted and asserted;
applying a data signal from said master latch to said third data input, wherein output signals at said third and fourth data outputs are functions of their respective data inputs when said clock signals at said third and fourth clock inputs are respectively asserted and de-asserted; and one of said first, second, third and fourth three-state stages having a clock switch element that receives clock signals from a clock signal source, provides said clock signals at said clock inputs of the same three-state stage and also provides said clock signals at said clock inputs of a different one of said first, second, third and fourth three-state stages.

12. The method of claim 11, wherein said first, second, third and fourth three-state stages comprise inverter stages including complementary pairs of semiconductor devices having signal paths connected in series, and control electrodes controlling said signal paths and receiving at least one of said data signals and said clock signals, and said first and second feedback stages comprise inverter stages.

13. The method of claim 11, wherein one of said master latch and slave latch includes said clock switch element and the other of said master latch and slave latch includes said different one of said first, second, third and fourth three-state stages.

14. The method of claim 13, wherein said master latch includes said clock switch element and said slave latch includes said different one of said first, second, third and fourth three-state stages.

15. The method of claim 11, wherein said second three-state stage comprises said clock switch element, which is connected to a power supply, and a data inverter connected in series with said clock switch element, wherein said third clock input receives said clock signal from said clock switch element of said second three-state stage.

16. The method of claim 13, wherein said third three-state stage comprises an inverter having a signal path receiving said clock signal from said clock switch element of said second three-state stage, and a control node receiving said data signal from an input of said first feedback stage.

17. The method of claim 11, wherein said first three-state stage comprises said clock switch element, which is connected to a power supply, and a data inverter connected in series with said clock switch element, and wherein said fourth clock input receives said clock signal from said clock switch element of said first three-state stage.

18. The method of claim 17, wherein said fourth three-state stage comprises an inverter having a signal path connected to said fourth clock input, and a control node that receives said data signal from an output of said second feedback stage.

19. The method of claim 11, wherein said first three-state stage comprises a first clock switch element connected to a power supply, and a first data inverter connected in series with said first clock switch element, said second three-state stage comprises a second data inverter connected to a power supply, and a second clock switch element connected in series with said second data inverter, said third three-state stage comprises a third switch element having a signal path receiving said data signal from said second data inverter and a control node receiving said clock signal from said clock signal source, and said fourth clock input receives said clock signal from said first clock switch element.

20. The method of claim 19, wherein said fourth three-state stage comprises an inverter having a signal path receiving said clock signal from said first clock switch element, and a control node receiving said data signal from an output of said second feedback stage.
